(19) United States
(12) Patent Application Publication
(10) Pub. No.: US 2006/0148122 A1
(43) Pub. Date: Jul. 6, 2006

(54) CMOS image sensor and method for manufacturing the same

(76) Inventor: Chang Hun Han, Icheon-city (KR)

Correspondence Address: Song K. Jung;MCKENNA LONG & ALDRIDGE LLP, 1900 K Street, N.W., Washington, DC, 20006, US

(21) Appl. No.: 11/319,597

(22) Filed: Dec. 29, 2005

(30) Foreign Application Priority Data
Dec. 30, 2004 (KR) P 2004-0116478

(51) Int. Cl. H01L 21/00

(52) U.S. Cl. 438/69; 438/65; 438/57

(57) ABSTRACT

A CMOS image sensor and a method for manufacturing the same are provided, in which a pad opening is formed simultaneously with the formation of a microlens. The CMOS image sensor includes a nitride layer for passivation deposited on an oxide layer, wherein a sacrificial microlens having a microlens structure is formed from a sacrificial microlens layer formed on the nitride layer and wherein, after forming the sacrificial microlens, the nitride layer is transfer-etched to impart the nitride layer with the microlens structure of the sacrificial microlens.

This application claims the benefit of Korean Patent Application No. 10-2004-0116478, filed on Dec. 30, 2004, which is hereby incorporated by reference for all purposes as if fully set forth herein.

### BACKGROUND OF THE INVENTION

1. Field of the Invention

The present invention relates to complementary metal-oxide-semiconductor (CMOS) image sensors, and more particularly, to a CMOS image sensor and a method for manufacturing the same, in which a pad opening is formed simultaneously with the formation of a microlens.

2. Discussion of the Related Art

FIGS. 1-6 respectively illustrate sequential process steps of a method for fabricating a CMOS image sensor according to a related art.

FIG. 1 illustrates a unit pixel region and a peripheral region of a pad, a P-well 50 and an N-well formed by selectively implanting boron ions into a silicon substrate. A field oxide layer 60 is formed by filling a trench using a device isolation process, then a gate oxide layer (not shown) is formed at a desired thickness according to a desired threshold voltage. A polysilicon layer 40 and a tungsten silicide layer 80 to be used as a gate electrode are formed on the gate oxide layer. Then, the polysilicon layer 40 and the tungsten silicide layer 80 are selectively etched to form the gate electrode of a device. Subsequently, an N-type ion-implantation region 20 and a P-type ion-implantation region 10 are formed in the silicon substrate by selective ion implantation to form a photodiode. The wells are lightly doped to form source and drain regions of a lightly doped drain structure. A tetra-ethyl-ortho-silicate oxide layer or a silicon nitride (SiN) layer is deposited by low-pressure chemical vapor deposition. The tetra-ethyl-ortho-silicate oxide layer or the silicon nitride layer is etched back to form a spacer 70 at sidewalls of the gate electrode. Then, an N-type junction region 30 and a P-type junction region are formed by heavily doping the silicon substrate to form source and drain regions.

As shown in FIG. 2, the tetra-ethyl-ortho-silicate oxide layer to be used as a pre-metal dielectric (PMD) layer 90 is formed to a thickness of 1,000Å by low-pressure chemical vapor deposition. A borophosphate-silicate-glass layer is formed on the tetra-ethyl-ortho-silicate oxide layer by high-pressure chemical vapor deposition. The borophosphate-silicate-glass layer then undergoes a heating process for flowing. Afterwards, a predetermined junction region and a contact hole 100 that exposes the gate electrode are formed by selectively etching the PMD layer 90. Subsequently, a titanium layer 110 serving as an adhesive layer, an aluminum layer 120 for interconnection, and a non-reflective titanium nitride (TiN) layer 130 are respectively deposited and selectively etched to form a first metal line. The contact hole 100 is formed by a plasma etching process.

As shown in FIG. 3, a tetra-ethyl-ortho-silicate oxide layer 150 and a spin-on-glass oxide layer 140 are formed by plasma-enhanced chemical vapor deposition. Then, the tetra-ethyl-ortho-silicate oxide layer 150 and the spin-on-glass oxide layer 140 undergo a heating process and planarization. Next, an oxide layer is deposited on the tetra-ethyl-ortho-silicate oxide layer 150 and the spin-on-glass oxide layer 140 by plasma-enhanced chemical vapor deposition to form a first IMD layer 160.

As shown in FIG. 4, a via hole is formed by selectively etching the first IMD layer 160. The titanium layer, the aluminum layer, and the titanium nitride layer are deposited and etched by a plasma etching process to form a second metal line. Subsequent formations of another tetra-ethyl-ortho-silicate oxide layer, another spin-on-glass oxide layer, and another oxide layer are formed in the same manner as the PMD layer 90 to form a second PMD layer. The above steps are repeated according to the required number of metal line layers.

shown in FIG. 5, after the uppermost metal line layer is formed, an oxide layer serving as a device passivation layer is deposited at a thickness of 8,000Å by plasma-enhanced chemical vapor deposition. A metal layer around a pad area is exposed by a pad opening process so that the metal pad may be used as an electrode terminal. That is, the oxide layer for the device passivation layer and the titanium nitride layer are etched to form a pad opening.

As shown in FIG. 6, a color filter array layer 170 is formed. A planarization layer 180 is formed thereon. Then, a microlens layer 190 is formed on the planarization layer 180. That is, in a CMOS image sensor according to the related art as described above, the color filter array and microlens layers are formed after the formation of the nitride layer for passivation. However, this results in a topology of the manufactured device that is too great to obtain a high quality image.

### SUMMARY OF THE INVENTION

Accordingly, the present invention is directed to a CMOS image sensor and a method for manufacturing the same that substantially obviates one or more problems due to limitations and disadvantages of the related art.

An advantage of the present invention is to provide a CMOS image sensor and a method for manufacturing the same, in which a pad opening is formed simultaneously with the formation of a microlens.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, there is provided a CMOS image sensor comprising a nitride layer for passivation deposited on an oxide layer, wherein a sacrificial microlens having a microlens structure is formed from a sacrificial microlens layer formed on the nitride layer and wherein, after forming the sacrificial microlens, the nitride layer is transfer-etched to impart the nitride layer with the microlens structure of the sacrificial microlens.

In another aspect of the present invention, there is provided a method for manufacturing a CMOS image sensor, the method comprising depositing a nitride layer for passivation on an oxide layer; forming a sacrificial microlens layer on the nitride layer; forming a sacrificial microlens from the sacrificial microlens layer; and shaping the nitride layer as the sacrificial microlens by a transfer etching process.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiment(s) of the invention and together with the description serve to explain the principles of the invention. In the drawings:

FIGS. 1-6 are cross-sectional views of a related art CMOS image sensor, respectively illustrating sequential process steps of a method for fabricating the CMOS image sensor according to a related art; and

FIGS. 7-10 are cross-sectional views of a CMOS image sensor according to the present invention, respectively illustrating sequential process steps of a method for fabricating the CMOS image sensor according to the present invention.

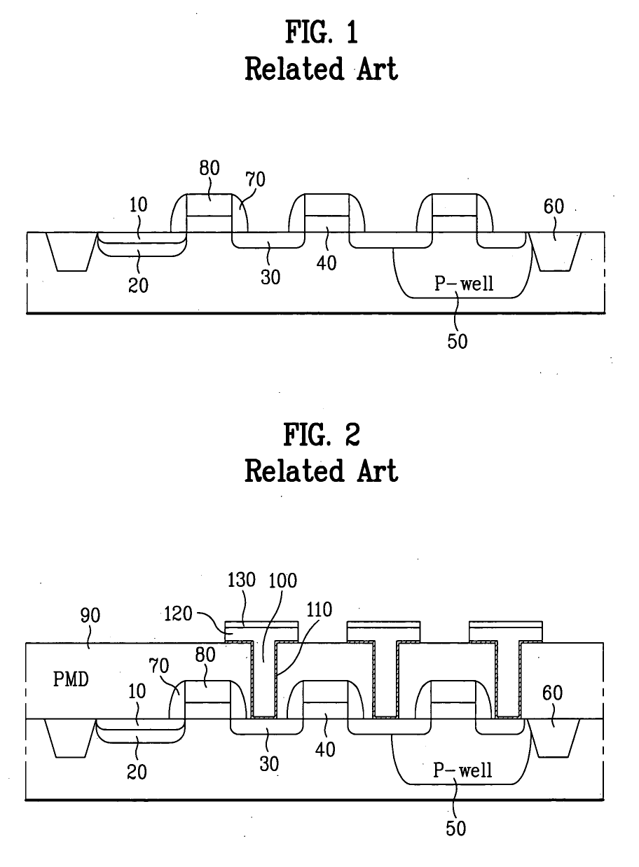

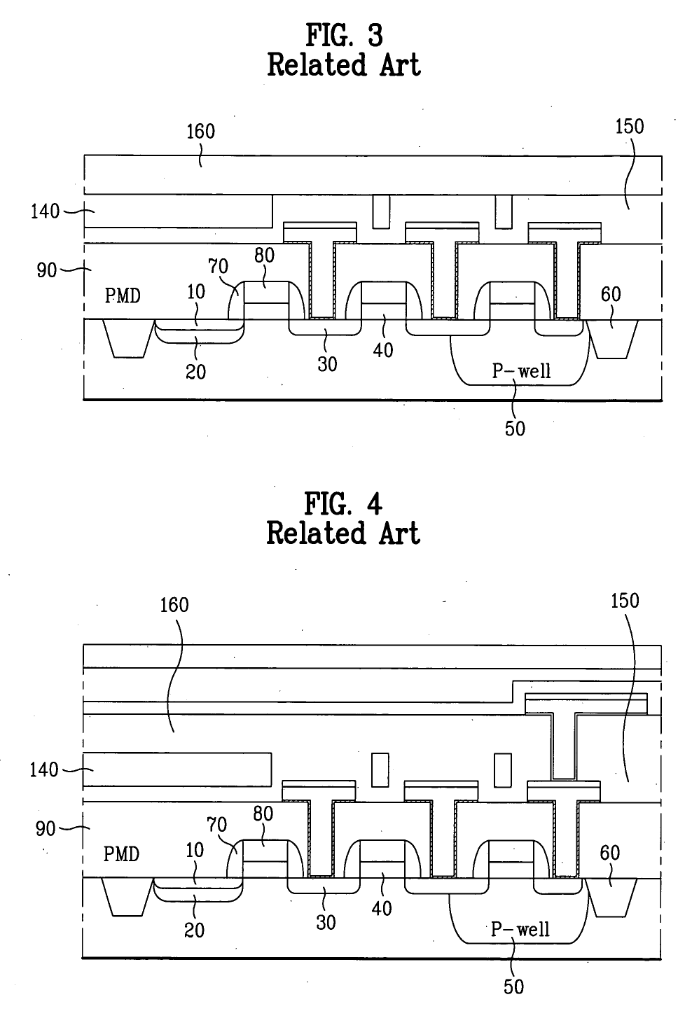

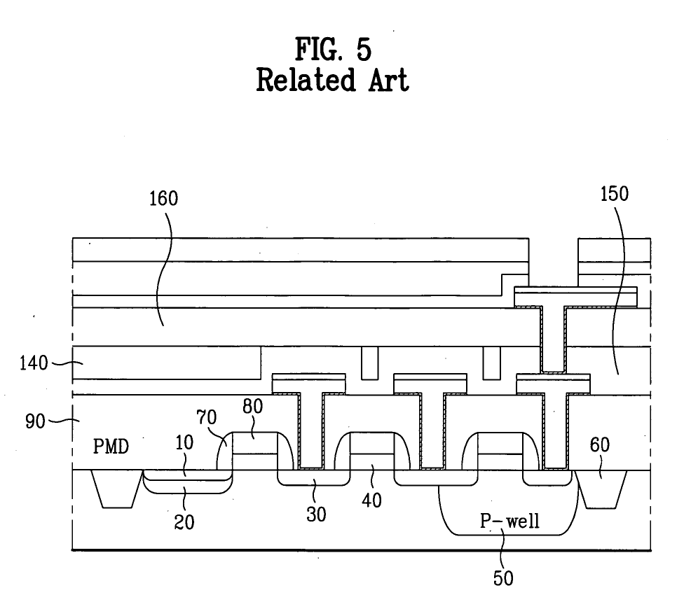

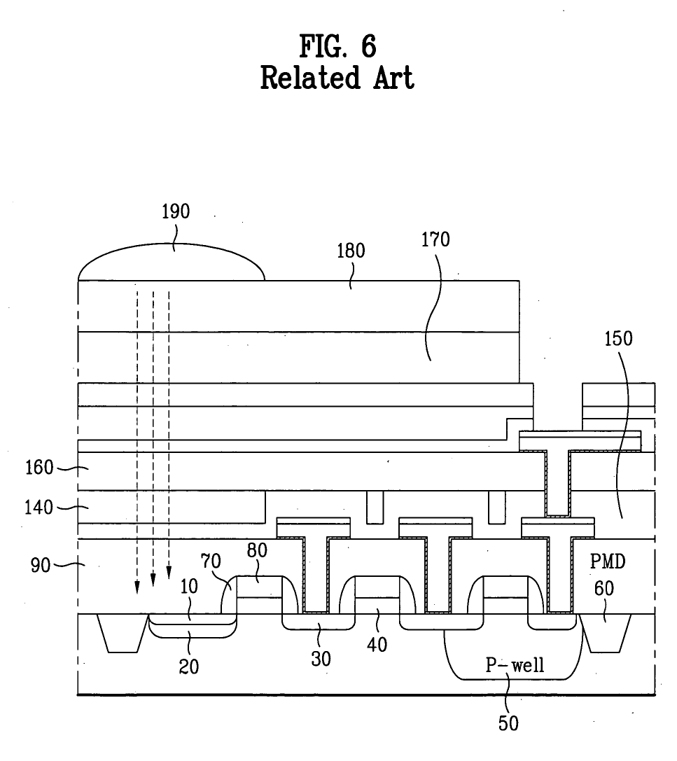

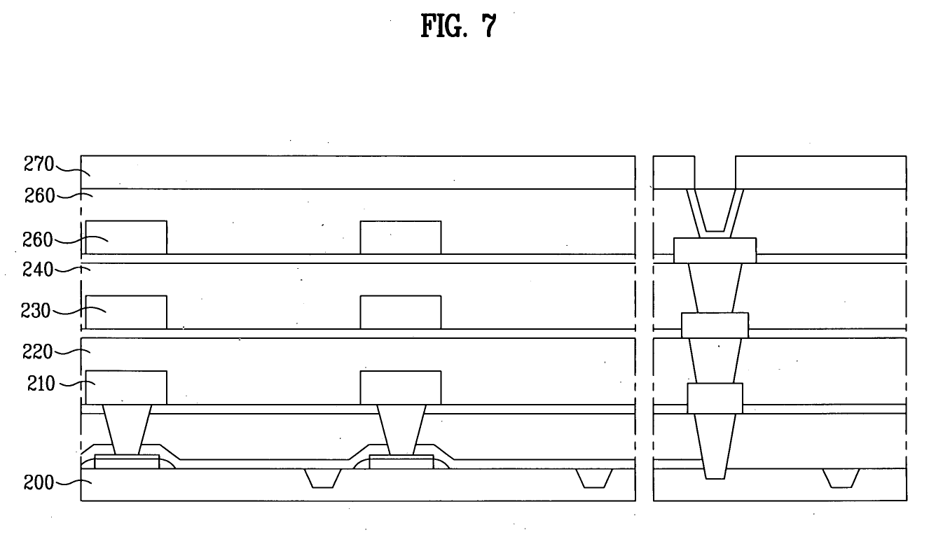

### DETAILED DESCRIPTION OF THE INVENTION

Reference will now be made in detail to embodiments of the present invention, examples of which are illustrated in the accompanying drawings. Wherever possible, like reference designations will be used throughout the drawings to refer to the same or similar parts.

As shown in FIG. 7, a photodiode 200 is formed, and an interlayer dielectric (ILD) layer is formed on the photodiode 200. A first metal layer 210 is formed on the ILD layer. The first metal layer 210 is connected with the photodiode 200 through an electrode. A first inter-metal dielectric (IMD) layer 220 is formed on the first metal layer 210. A second metal layer 230 is formed on the first IMD layer 220. A second IMD layer 240 is formed on the second metal layer 230. An upper metal layer 250 is formed on the second IMD layer 240. An oxide layer 260 in which a pad is opened is formed on the upper metal layer 250. A nitride layer 270 for passivation is formed on the oxide layer 260. It is noted that a portion where the pad is opened is formed in the oxide layer 260 and the nitride layer 270.

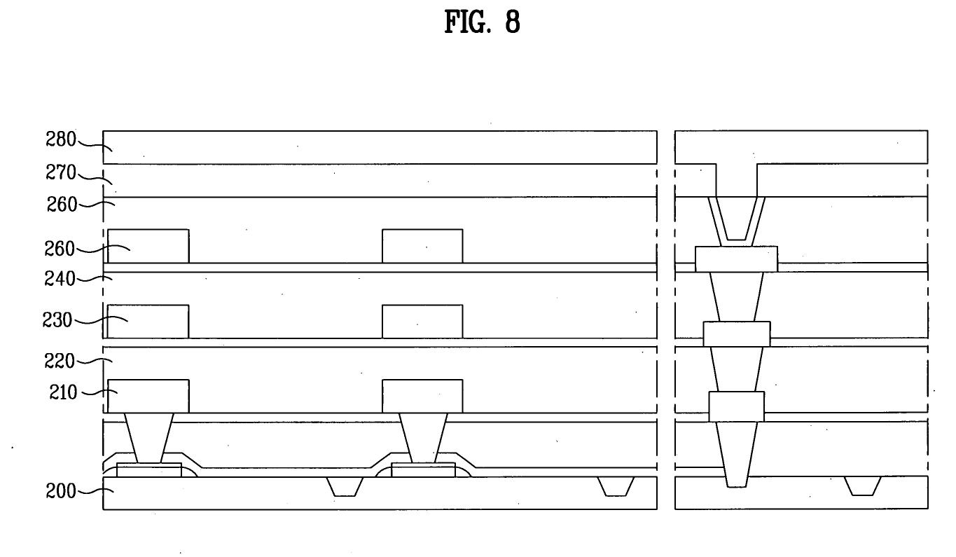

As shown in FIG. 8, a sacrificial microlens layer 280 is formed on the nitride layer 270. It is noted that the sacrificial microlens layer 280 is formed even in the portion where the pad is opened.

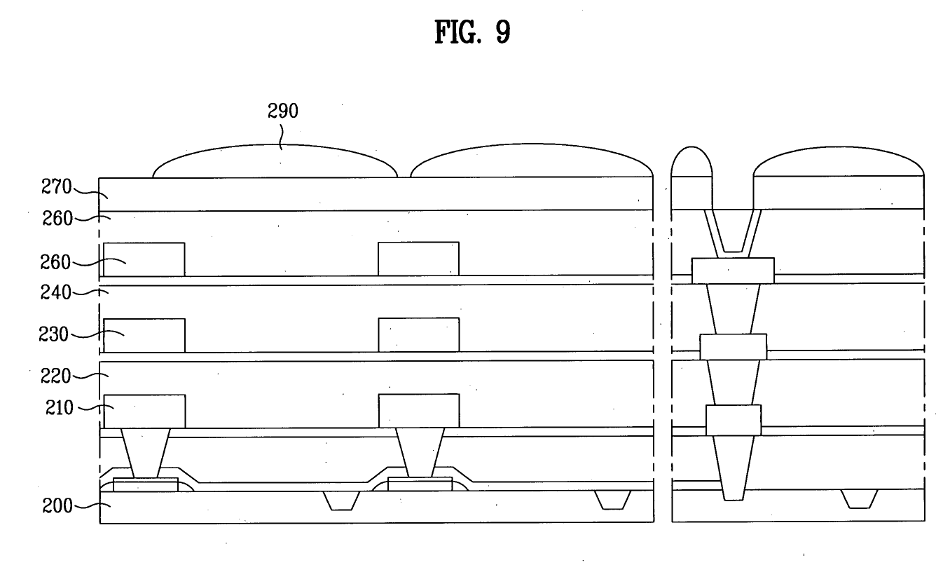

As shown in FIG. 9, a sacrificial microlens 290 is formed from the sacrificial microlens layer 280. It is noted that the portion where the pad is opened is in the same state as that of FIG. 7 even if the sacrificial microlens layer 280 is formed in the portion where the pad is opened as shown in FIG. 8.

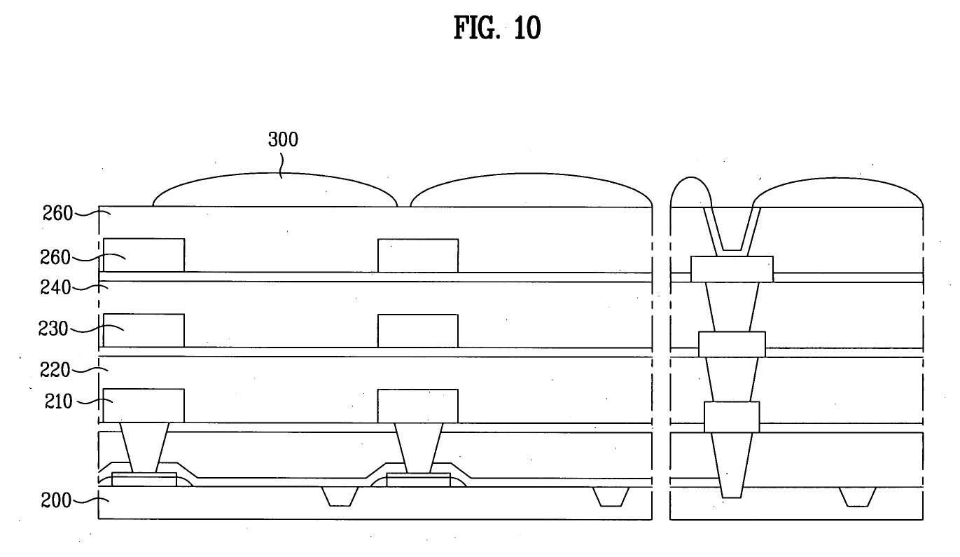

As shown in FIG. 10, the nitride layer 270 is imparted with the same shape as that of the sacrificial microlens 290 by a transfer etching process, whereby the sacrificial microlens 290 is wholly removed. At the same time the sacrificial microlens 290 is wholly removed, the nitride layer 270 is etched to expose the pad. The nitride layer 270 and the sacrificial microlens 290 are etched at a dry etching ratio of 1:1. The sacrificial microlens layer 280 is formed only in a pixel array so that the pad of the nitride layer 270 is automatically opened when a microlens 300 is formed.

In the structure of a CMOS image sensor fabricated as described above, the nitride layer 270 for passivation is deposited on the oxide layer 260, and the sacrificial microlens 290 is formed. Then, the nitride layer 270 and the sacrificial microlens 290 are both etched using a transfer etching process. That is, the sacrificial microlens layer 280 is formed on the nitride layer 270, and the sacrificial microlens 290 is formed from the sacrificial microlens layer 280. That is, the sacrificial microlens 290, which has a microlens structure corresponding to the desired microlens 300, is formed from the sacrificial microlens layer 280 formed on the nitride layer 270. Then, after forming the sacrificial microlens 290, the nitride layer 270 is transfer-etched, along with the sacrificial microlens 290, to impart the nitride layer 270 with the microlens structure of the sacrificial microlens 290. Thus, microlens 300 is formed.

By adopting the CMOS image sensor and the method for manufacturing the same, the pad opening is formed simultaneously with the formation of the microlens 300. Therefore, it is possible to reduce the topology due to a formation of a color filter array and the microlens after the nitride layer for passivation is formed. This improves image quality.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A CMOS image sensor, comprising:
a nitride layer for passivation deposited on an oxide layer,
wherein a sacrificial microlens having a microlens structure is formed from a sacrificial microlens layer formed on said nitride layer and wherein, after forming the sacrificial microlens, said nitride layer is transfer-etched to impart said nitride layer with the microlens structure of the sacrificial microlens.

2. The CMOS image sensor of claim 1, further comprising:
a photodiode;
an interlayer dielectric layer formed on the photodiode; and
a first metal layer connected to the photodiode through an electrode, wherein the oxide layer is formed on the first metal layer.

3. The CMOS image sensor of claim 2, further comprising:
a first inter-metal dielectric layer;
a second metal layer;
a second inter-metal dielectric layer; and
an upper metal layer, wherein the oxide layer is formed on the upper metal layer.

4. A method for manufacturing a CMOS image sensor, comprising:
depositing a nitride layer for passivation on an oxide layer;
forming a sacrificial microlens layer on the nitride layer;
forming a sacrificial microlens from the sacrificial microlens layer; and
shaping the second nitride layer as the sacrificial microlens by a transfer etching process.

5. The method of claim 4, wherein the nitride layer and the sacrificial microlens are etched at a dry etching ratio of 1:1.

6. The method of claim 4, wherein the sacrificial microlens layer is formed only in a pixel array.

7. The method of claim 4, further comprising:
forming a photodiode;
depositing an interlayer dielectric layer on the photodiode;
depositing a first metal layer on the interlayer dielectric layer; wherein the oxide layer is formed on the first metal layer.

8. The method of claim 7, further comprising:
depositing a first inter-metal dielectric layer on the first metal layer;
depositing a second metal layer on the first inter-metal dielectric layer;
depositing a second inter-metal dielectric layer on the second metal layer; and
depositing an upper metal layer on the second inter-metal dielectric layer, wherein the oxide layer is formed on the upper metal layer.
